(19) United States
(12) Patent Application Publication
(10) Pub. No.: US 2016/0245875 A1
(43) Pub. Date: Aug. 25, 2016

(54) METHOD FOR MONITORING A LI-ION BATTERY AND MONITORING DEVICE FOR THE IMPLEMENTATION OF THIS METHOD

(71) Applicants: COMMISSARIAT A L'ENERGIE ATOMIQUE ET AUX ENERGIES ALTERNATIVES, Paris (FR); UNIVERSITE GRENOBLE ALPES, Saint-Martin-d'Hères (FR); INSTITUT POLYTECHNIQUE DE GRENOBLE, Grenoble (FR)

(72) Inventors: Nina Kircheva, Aix Les Bains (FR); Pierre-Xavier Thivel, Grenoble (FR); Sylvie Genies, Saint Egreve (FR); Mélanie Alias, Poligny (FR); Sothun Eric Hing, Chambéry (FR)

(73) Assignees: COMMISSARIAT A L'ENERGIE ATOMIQUE ET AUX ENERGIES ALTERNATIVES, Paris (FR); UNIVERSITE GRENOBLE ALPES, Saint-Martin-d'Hères (FR); INSTITUT POLYTECHNIQUE DE GRENOBLE, Grenoble (FR)

(21) Appl. No.: 15/026,087

(22) PCT Filed: Sep. 30, 2014
(86) PCT No.: PCT/EP2014/070983

§ 371 Date: Mar. 30, 2016

(30) Foreign Application Priority Data
Sep. 30, 2013 (FR) 1359428

(51) Int. Cl. G01R 31/36

(52) U.S. Cl. CPC G01R 31/3651; G01R 31/3679

(57) ABSTRACT

Method for determining the state of health of a battery, using a sensor of the acoustic activity of the battery, comprising the following steps:
detection of at least one acoustic event by the sensor;
determination of the value of at least one parameter for each acoustic signal detected in the course of the elementary cycle of use;
calculation, for the elementary cycle of use, of a value of acoustic density according to a density calculation function taking into account said at least one parameter determined for each of the acoustic signals detected in the course of the cycle;
calculation of a state of health value corresponding to said previously calculated acoustic density value, on the basis of a functional relation or a predetermined database, making it possible to know the state of health for a given acoustic density value.

The present invention concerns the field of accumulator batteries of the lithium ion or “Li-ion” type. In particular, the invention concerns a method for monitoring an electrochemical cell or a battery. The invention also relates to a monitoring device implementing the monitoring method.

The invention relates to the field of energy storage, and more particularly to the field of lithium ion or “Li-ion” batteries.

The development of a health indicator has become essential for the provision of reliable information to the user, for both on-board and stationary applications. The state of health (SOH) is an indication of battery wear. It is the ratio of the total amount of storable electrical energy (Cp) to the initial storage capacity (Cp initial), that is to say the ratio of the effective storage capacity (Cp) to the initial storage capacity (Cp initial).

The SOH parameter characterizes the ageing of a battery, that is to say its degree of degradation in the course of its use, in terms of lost capacity (that is to say, loss of range) and in terms of performance (delivered power). State of health indicators can potentially differ considerably, and may be based on electrochemical quantities (capacity measurement and electrical resistance). Electrochemical indicators are affected by the operating temperature of the battery, making them difficult to use.

The onset of battery ageing is due to electrochemical or chemical mechanisms which degrade the internal components. The internal mechanisms responsible for battery ageing are:
the degradation of the electrolyte, due to its limited range of electrochemical stability. This degradation causes the evolution of gas by decomposition of the solvent molecules;
the ageing of the passivation film, if any, formed on the surface of the particles (in the case of graphite-based electrodes, for example). This ageing corresponds to mechanical phenomena due to fracturing of the passivation layers and gas production by formation of a new passivation layer when the lithiated electrode comes back into direct contact with the electrolyte. These events give rise to mechanical stress on the materials;
the degradation of the electrode materials. This implies micro-fractures within the crystal structures, changes of phase or atomization of particles, and gas formation;
the corrosion of the current collectors.

The combination of these mechanisms results in an irreversible loss of performance and an accumulation of forces or mechanical stresses within the accumulator.

These degradation reactions cause gas to be produced by decomposition of the electrolyte or corrosion of the collector, decomposition of the passivation film, breakdown of the crystal structure or atomization of particles.

The state of health indicators which have been developed up to the present time, or are in the course of development, are essentially based on the variation of the two electrical parameters of current and voltage, and of the quantities related to these:
The coulomb count (or ampere-hour metric). This is an accurate indicator, provided that there is a recalibration function and the current can be measured precisely;
Impedance measurement and extraction of characteristic parameters based on an equivalent circuit model. This is an accurate indicator, but is temperature-sensitive. It is also difficult to implement.

Consequently, it will be useful to have an indicator which is not temperature-dependent and is easily implemented.

Given that performance loss during cycling (under current/voltage stress) or over time (without stress) is caused by crystalline degradation of the active materials present in the electrodes, by losses of cohesion of these structures due to expansion phenomena (contraction of the particles), or by gas emissions which generate acoustic phenomena, and given that these can be detected by special sensors, the acoustic signals may be related to the state of health of the accumulator, and new state indicators in the control systems of batteries based on acoustic parameters may be envisaged.

The document EP2575205 discloses a method for detecting a change of state in a battery. This method requires a preliminary step of calibration based on a test battery of the same type as that which will subsequently be used, to determine an acoustic signature of the test battery for different internal states of the battery. The determination of these signatures requires very large storage and computing resources. The detection of a change of state in a battery in the course of use consists in detecting a modification of the acoustic signature over time and comparing the present acoustic signature with previously stored reference signatures. Here again, this method requires high computing capacity. These constraints make the method unsuitable for detecting a change of state in real time.

The object of the invention is to provide a monitoring method which can overcome the aforementioned problems while improving the monitoring methods known from the prior art. In particular, the invention proposes a battery monitoring method which is simple, reliable, non-intrusive, and economical.

According to the invention, the method for determining the state of health of a battery uses a sensor of the acoustic activity of the battery, and comprises the following steps:
the detection, notably the detection during operation, of at least one acoustic event by the detector in the course of an elementary cycle of use of the battery, corresponding to a period of use of the battery with charging and/or discharging operations;
the determination, notably determination during operation, of the value of at least one parameter for each acoustic signal detected in the course of the elementary cycle of use;
the calculation, notably calculation during operation, for the elementary cycle of use, of a value of acoustic density according to a density calculation function taking into account said at least one parameter determined for each of the acoustic signals detected in the course of the cycle, the density calculation function being a monotonic function based on the number of events detected during the elementary cycle;
the calculation, notably calculation during operation, of a state of health value corresponding to said acoustic density value calculated previously, based on a functional relation or on a predetermined database, making it possible to know the state of health for a given acoustic density value.

According to the invention, the method for characterizing a test battery uses a sensor of the acoustic activity of the test battery, and comprises a number of successive test operations performed during successive elementary cycles of use of the test battery, each test operation comprising the following steps:
the detection, notably the detection during operation, of at least one acoustic event by the sensor in the course of an elementary cycle of use of the test battery, corresponding to a period of use of the test battery with charging and/or discharging operations;
the determination, notably determination during operation, of the value of at least one parameter for each acoustic signal detected in the course of the elementary cycle of use;
the determination, notably determination during operation, for the elementary cycle of use, of a value of acoustic density according to a density calculation function taking into account said at least one parameter determined for each of the acoustic signals detected in the course of the cycle, the density calculation function being a monotonic function based on the number of events detected during the elementary cycle;
the determination, notably determination during operation, in the course of the elementary cycle or at the end thereof, of the state of health of the test battery;
the storage, notably storage during operation, in a database, of the state of health and the acoustic density value determined previously for the elementary cycle concerned.

The calculation of a state of health value corresponding to an acoustic density value may be carried out on the basis of a predetermined database, according to the characterization method defined above.

The characterization method may further comprise a step of determining a functional relation which makes it possible to know the state of health of the test battery for a given acoustic density value, based on said database.

The calculation of a state of health value corresponding to an acoustic density value may be carried out on the basis of a predetermined database, according to the characterization method defined in the preceding paragraph.

At least one parameter may correspond to the detection of an acoustic event, and the acoustic density value defined for an elementary cycle may correspond to the number of events detected during the cycle.

The method may comprise, following the step of determining an acoustic density value for the elementary cycle current, a step of calculating a smoothed acoustic density value corresponding to a mean of the N most recent acoustic density values, wherein the smoothed acoustic density value may be stored in the database and/or used for the state of health calculation.

At least one parameter of an acoustic signal may be chosen from the following list:
amplitude of the acoustic signal;
energy of the acoustic signal;
rise time of the acoustic signal;
frequency of the oscillations of the acoustic signal;
duration of the acoustic signal;
number of “hits” in the acoustic signal, a hit corresponding to a passage beyond a threshold;
frequency of acoustic hits, that is to say the number of acoustic hits per unit of time in the acoustic signal;
presence of an acoustic event.

The density value may correspond to a sum of the values of said at least one parameter of the acoustic signal.

The attached drawings show, by way of example, an embodiment of a monitoring device according to the invention.

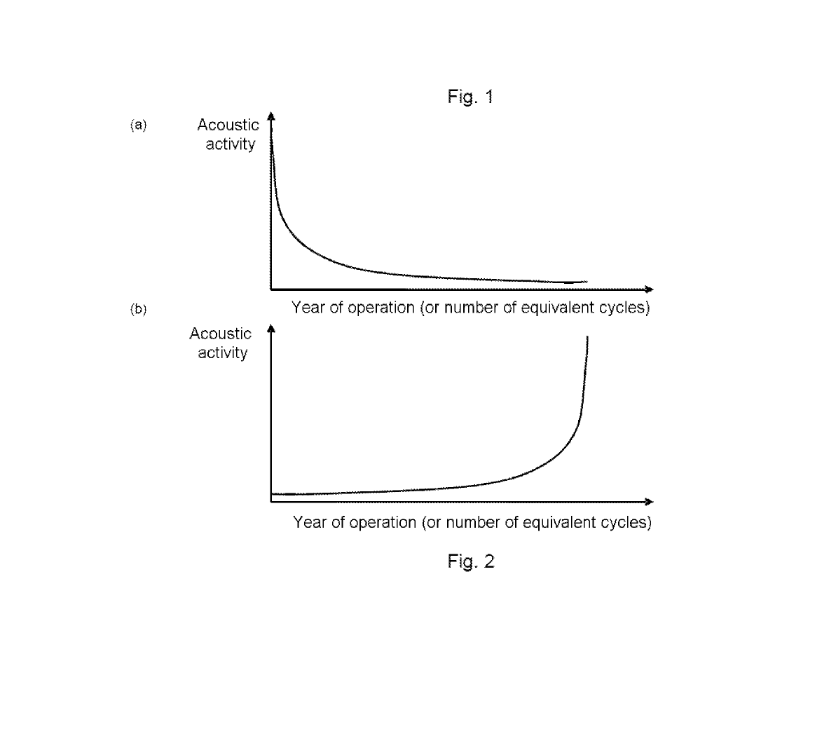

FIG. 1 is a graph showing the variation of the acoustic activity intensity over time for a first type of battery.

FIG. 2 is a graph showing the variation of the acoustic activity intensity over time for a second type of battery.

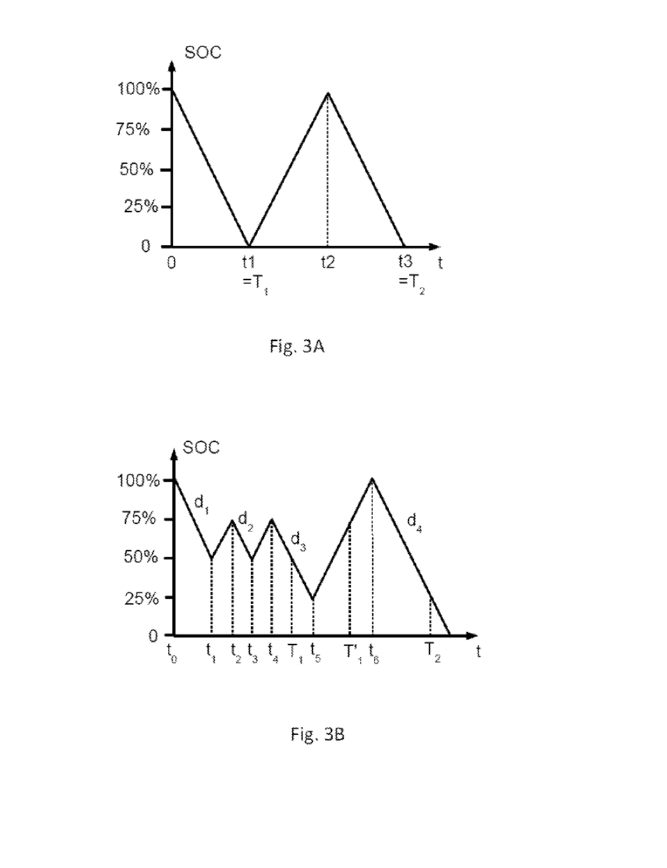

FIGS. 3A and 3B are diagrams showing a principle of equivalence between operation with complete charge and discharge cycles (3A) and operation with partial charge and discharge cycles (3B).

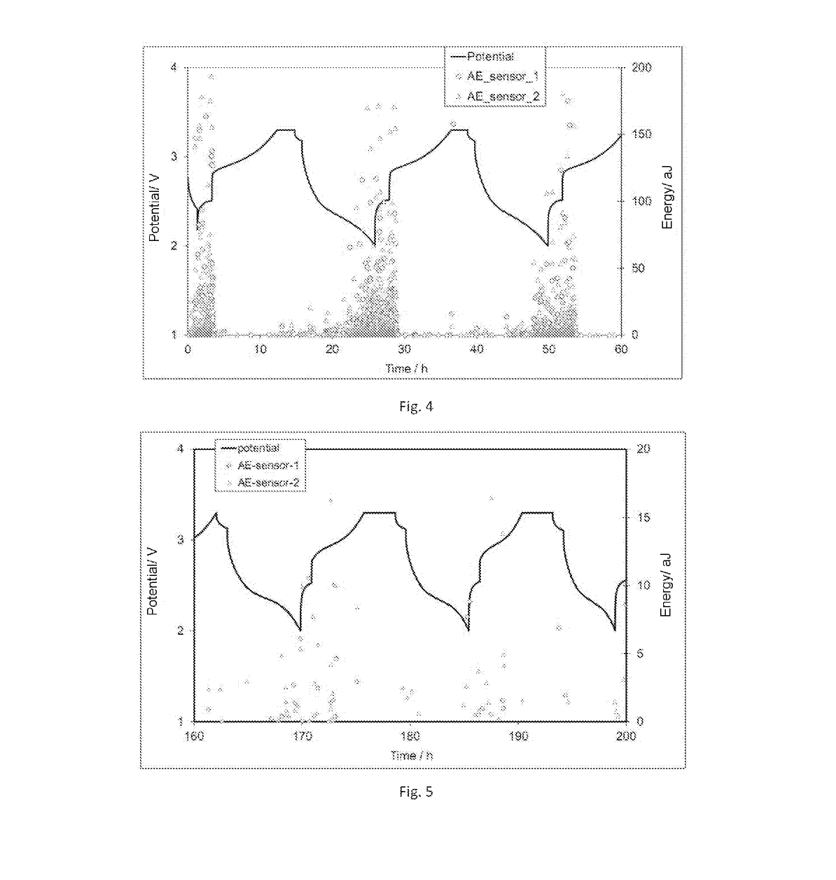

FIG. 4 is a graph showing the variation of the acoustic activity detected by two sensors placed on a battery, together with the variation of the battery voltage over a number of cycles in a first time range corresponding to the start of the battery life.

FIG. 5 is a graph showing the variation of the acoustic activity detected by two sensors placed on a battery, together with the variation of the battery voltage over a number of cycles in a second time range corresponding to the end of the battery life.

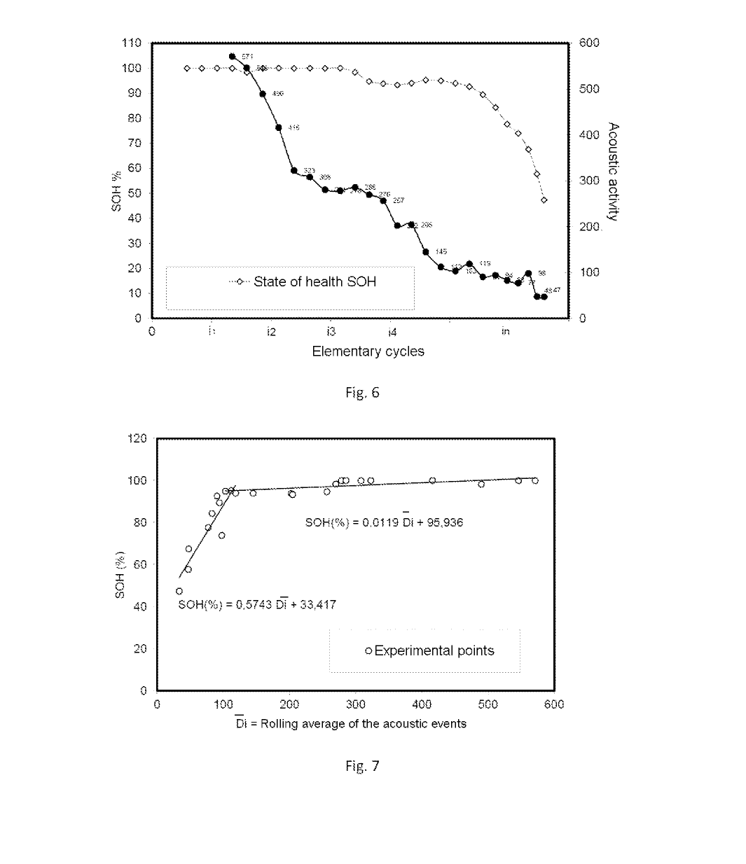

FIG. 6 is a graph showing the variation in time of the state of health of a battery and a rolling average of the density of the acoustic phenomena in a battery over the same period.

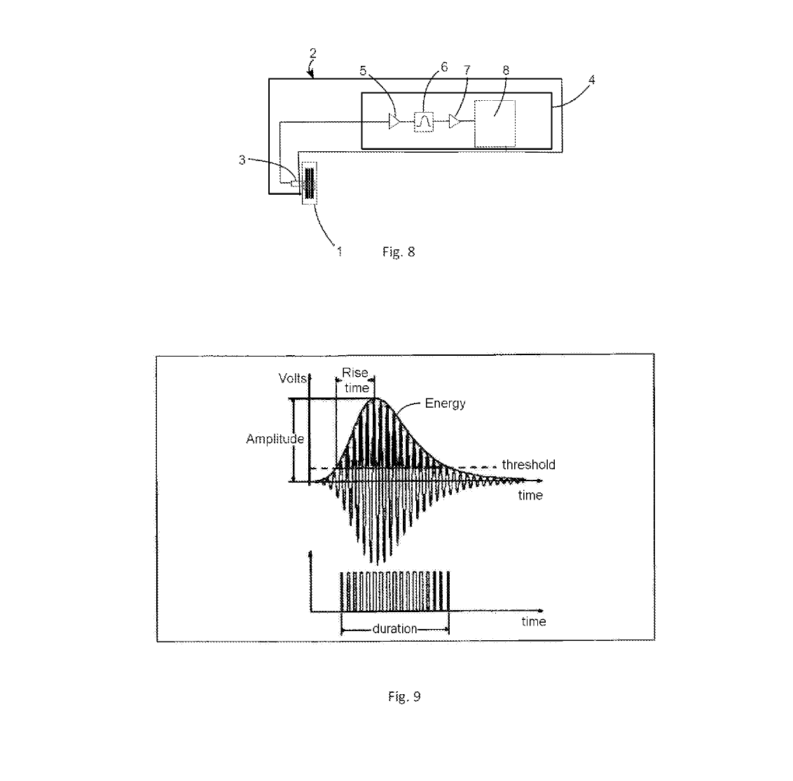

FIG. 7 is a graph showing the linear regression straight lines which can be used to model a relationship present between the state of health of a battery and a rolling average of the intensity of an acoustic parameter.

FIG. 8 is a diagram of an embodiment of a monitoring device according to an embodiment of the invention.

FIG. 9 is a flow diagram showing different parameters that can be used to characterize an acoustic emission.

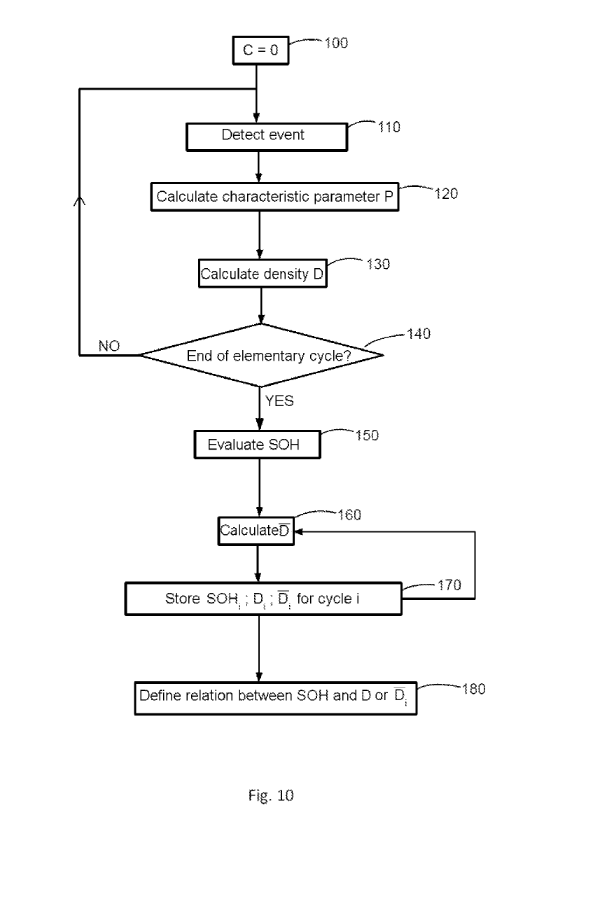

FIG. 10 is a flow diagram of an embodiment of a characterization method according to the invention.

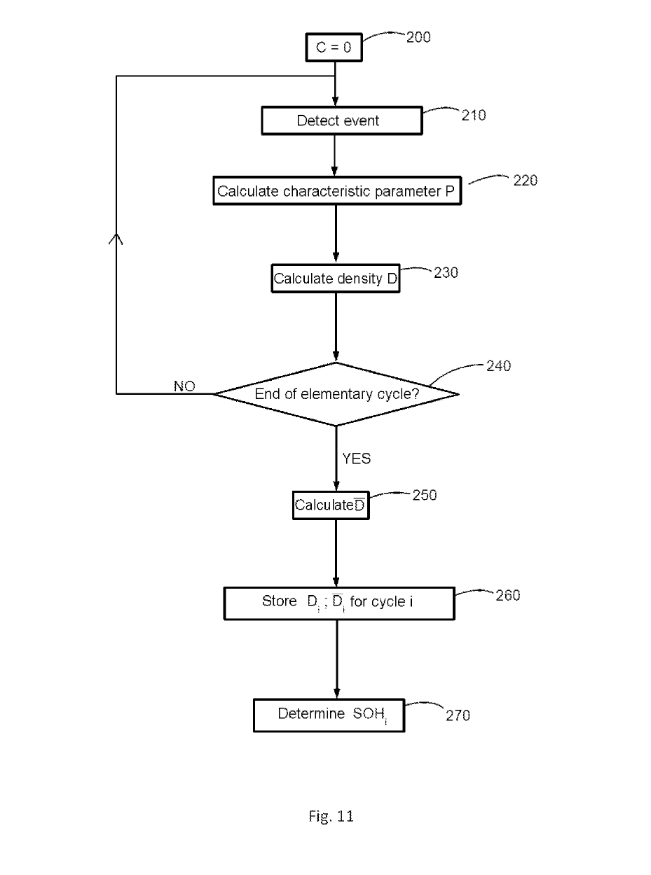

FIG. 11 is a flow diagram of an embodiment of a monitoring method according to the invention.

As indicated above, all the internal phenomena contributing to the degradation of the battery's performance lead, as a general rule, to the emission of mechanical waves during the degradation of the components and the formation of gas. All these phenomena result in the emission of acoustic signals detectable by acoustic sensors in particular frequency ranges.

An acoustic emission is defined as a phenomenon of creation of transient elastic waves due to local micro-displacements within a material. In other words, this physical phenomenon can be used to detect and locate degradation which develops under the action of a mechanical stress of any kind. Thus acoustic emissions not only locate developing faults, but also provide information on their kinetics and on their development processes. The frequency range is typically between 50 kHz and 1.5 MHz.

The invention relates to the use of acoustic emission signals, emitted by a cell or a battery during its operation, particularly during its operation in an authorized voltage range. These acoustic signals are used and processed to provide information on the state of health. Depending on the state of health, the cell or battery may be considered to be non-operational for its application, or even dangerous for the user or the environment. It is also possible to correct other parameters of the battery, such as the state of charge or the state of energy, when the state of health is known.

Thus the invention is based on the analysis of acoustic signals for establishing an indicator of the state of health of the battery. For this purpose, the acoustic events are monitored continuously throughout the life of the battery, regardless of whether the battery is being used in charging or discharging phases, or is at rest. The recorded acoustic activity can be used to obtain information on the state of health of the battery, as explained below. This variation depends on the battery technology and therefore on the mechanisms of degradation affecting the materials. The analysis of the variations depends on the lithium technology used.

FIG. 1 shows an example of the variations that may be observed in the case of a lithium technology using materials for which the incorporation of lithium takes place with modifications of the crystal structure and of the chemical composition of the material, for example conversion reaction compounds such as CoO, Co₃O₄, CuO, FeO . . . , or lithium alloys formed from the pure metal (Si, Sn, Al, Sb . . . ) or formed in two stages (SnO, Cu₆Sn₅). It can be seen that the acoustic activity diminishes rapidly during the first use of the battery, and decreases more slowly thereafter.

FIG. 2 shows an example of the variations that may be observed in the case of a lithium technology using materials for which the incorporation of lithium takes place without any major change in the crystal structure for intercalation into a two-dimensional structure such as compounds of the graphite or lamellar oxide LiMnO₂ type or in a three-dimensional structure such as spinel oxides, for example LiMn₂O₄. It can be seen that the acoustic activity increases very slowly during the first use of the battery, and rises very rapidly in the final use.

In the case of FIG. 1, the acoustic activity decreases as the cell ages and therefore loses capacity, because a smaller proportion of the active material is participating in the electrochemical reactions. This loss of capacity and acoustic emission is due, for example, to the atomization of the metal grains during the formation of the lithium compound: there is a loss of contact between the grains of active material and the polymer binder in which the network of particles is embedded. Smaller and smaller grains are formed, leading to a loss of electrical contact and a reduction of acoustic noises.

In the case of FIG. 2, crystallized materials of the intercalation or insertion type are present. These structures are “quieter” during cycling, once the formation and entrainment cycles have been completed. For this type of element, the acoustic emissions in ageing are characteristic of the fracture of the passivation film and/or the degradation of the intercalation structures. In this case, the acoustic activity increases with time.

In order to implement a mode of execution of the monitoring method according to the invention, the cycling operations of a battery are “cut” into a sequence of elementary cycles. Each elementary cycle is defined by using a reference value of a quantity representative of the cycling, that is to say of the charging and discharging operations. By way of example, and as described in greater detail below, the following representative quantities may be considered: a value of capacity in Ah, a value of variation of state of charge SOC, a value of energy, or a time of use in charging/discharging. Thus start and end instants of the elementary cycle are defined, a positive and/or negative variation of the representative quantity being determined, corresponding to the chosen reference value.

This method will be more easily understood from the following illustrative examples, provided with reference to FIGS. 3A and 3B which show the state of charge SOC as a function of time.

The first case, shown in FIG. 3A, is that of a sequence of complete charge/discharge cycles, such as those executed during testing in a laboratory. At the initial instant t0, the SOC is equal to 100%; the battery is then discharged completely up to an instant t1 where the SOC is equal to 0%, and is then charged completely up to an instant t2 where the SOC is equal to 100%, and so on.

The second case shown in FIG. 3B corresponds to a use of the battery. A sequence of cycles of varying amplitude can be seen, with partial or complete discharges and recharges. In this example, at the initial instant t0, the SOC is equal to 100%, then a partial discharge d1 up to an instant t1 brings the SOC to 50%, a recharge up to an instant t2 brings the SOC to 75%, a discharge d2 up to an instant t3 brings the SOC to 50%, a recharge up to an instant t4 brings the SOC to 75%, a discharge d3 up to an instant t5 brings the SOC to 25%, a partial recharge to 100% brings the SOC to 100%, and a complete discharge d4 brings the SOC to 0%.

In a first example, an elementary cycle is defined by using a reference capacity value Cref which may be taken to be equal to the nominal capacity of the battery, that is to say the number of ampere-hours that can be stored in the battery in nominal conditions of battery use in terms of the current of use and temperature at the start of the battery life. It should be noted that the nominal capacity of the battery corresponds to the quantity of ampere-hours delivered during a discharge of the battery between an SOC of 100% and 0%, and to the quantity of ampere-hours that are stored during the charging of the battery between 0% and 100%.

An elementary cycle is then considered to have been completed when the integral of the current of the discharge operations, that is to say the quantity of ampere-hours delivered, identical to a value of capacity in Ah, is equal to this reference capacity value.

In the simplest example of FIG. 3A, therefore, a first elementary cycle is considered to lie between the instants t0 and t1, and a second elementary cycle is considered to lie between the instants t1 and t3.

From a practical point of view, the method may monitor a quantity called the “discharge capacity, Cdischarge”, corresponding to the integral of the current in discharge, between an instant of reinitialization corresponding to the start of an elementary cycle and the present instant, and may determine the instant of the end of an elementary cycle as being when the discharge capacity is equal to the predefined reference capacity.

In the example of FIG. 3B, therefore, it is considered that the discharge capacity Cdischarge is incremented by Cref/2 between t0 and t1, incremented by Cref/4 between t2 and t3, and then incremented by Cref/2 up to an instant T1 located between t4 et t5. Thus, at the instant T1, the discharge capacity Cdischarge is equal to Cref, and T1 corresponds to the end of the first elementary cycle and the start of the next elementary cycle. Using the same calculation, the end of the second elementary cycle corresponds to an instant T2 during the discharge d4 at the moment when the SOC is equal to 25%.

Similarly, it is possible to define an elementary cycle by considering a quantity called the “charge capacity, Ccharge”, corresponding to an integral of the current in charging, between an instant of reinitialization corresponding to the start of an elementary cycle and the present instant.

It is also possible to consider a combination of the charge capacity Ccharge and the discharge capacity Cdischarge (called Cmean, for example) to define the start and end instants of an elementary cycle, for example by considering that an elementary cycle is terminated when the charge capacity Ccharge and discharge capacity Cdischarge have both reached the predefined reference capacity.

As a person skilled in the art will understand, the monitored quantities Ccharge, Cdischarge and Cmean are zero at the start of life, and are reinitialized whenever an elementary cycle terminates.

If required, the reference capacity value may itself be corrected, using a state of health measured over time. Thus the determination of the elementary cycles allows for the variation in the effective capacity of the battery.

In a second example, an elementary cycle is defined by using a reference value of variation of state of charge SOC, equal to 100% for example. It is then considered that an elementary cycle has been completed when the negative variation of SOC is equal to 100%, as is the case, for example, between the instants t0 and t1, and between t1 and t3 in FIG. 3A, or between the instants t0 and T1 and between the instants T1 and T2 in FIG. 3B. Similarly, it may be considered that an elementary cycle has been completed when the positive variation of SOC is equal to 100%, as is the case, for example, between the instants t0 and t2, in FIG. 3A, or between the instants t0 and T′1 in FIG. 3B, where T′1 corresponds to an instant located between t5 and t6, for which the SOC is equal to 75%. Proceeding in the way described above for capacity, in the case of a variation of SOC it is possible to consider that an elementary cycle is terminated when the positive variation and negative variation of SOC have both reached the reference value of 100% in this example.

According to a third example, an elementary cycle is considered to be defined by a duration of use, that is to say a cumulative time of active charging and discharging phases, without taking into account any intermediate rest periods. This is substantially equivalent to a charge and discharge capacity calculation, if the charging/discharging current is constant.

In the above examples, an elementary cycle is defined on the basis of a variation of a quantity during the equivalent of a complete charge/discharge cycle, but it would be possible to consider an amplitude of variation of this physical quantity corresponding to a fraction of a complete cycle or corresponding to a number of complete charge/discharge cycles. Additionally, although the examples described in relation to FIGS. 3A and 3B concern continuous charging and discharging, the different charging and discharging phases may be interrupted (spaced apart) by rest phases.

An example of a battery that can be monitored by using the method proposed by the invention is an LiAl/LiMnO₂ battery, consisting of a lithium-aluminium (LiAl) intermetallic alloy, for the negative electrode, and an intercalation material, lithium manganese dioxide (LiMnO₂), for the positive electrode. The reactions taking place are shown in FIG. 5 for each electrode. The balance reaction is also shown in the general case and in the case where x=1.

FIGS. 4 and 5 are graphs showing the acoustic activity that has been continuously recorded during the cycling of a battery carried at a rate of C/20, that is to say with a charging current enabling the battery to be completely charged in 20 hours. A sensor, AE-sensor-1, was placed at the positive pole of the battery. A sensor, AE-sensor-2, was placed at the negative pole of the battery. The charging and discharging phases are separated by zero-current relaxation phases. It can be seen that the acoustic activity varies with the battery voltage, and that it is relatively high in the relaxation phases after discharge (before a new charge begins). Here also, it can be seen (by comparing FIGS. 4 and 5) that there is a reduction in the intensity of an acoustic emission parameter over time.

Using different tests on batteries of the same type, graphs such as those shown in FIGS. 6 and 7 can be plotted. Graph 6 shows the variations of the state of health and the acoustic activity as a function of the number of elementary cycles completed. The state of health is expressed as a percentage relative to a reference capacity value. The acoustic activity shown corresponds to a rolling average D̅ᵢ of a parameter D representing a density of acoustic events (hits) in the case of complete charge and discharge cycles. In the illustrated example, the state of health decreases with the acoustic activity. The graph of FIG. 7 shows the state of health SOH as a function of a smoothed density D̅ᵢ corresponding, in the illustrated example, to a rolling average of a number of acoustic events detected per elementary cycle. It can be seen that a relation between the acoustic activity, represented by D̅ᵢ, and the state of health can be determined by linear regression laws. As shown in FIG. 7, a first linear relation with a small gradient can be used to model the relation between a high SOH (start of battery life) and a smoothed density D̅ᵢ of events greater than 100 acoustic events detected per elementary cycle. A second linear relation with a larger gradient can be used to model the relation between a degrading SOH, from less than 98% to 50%, and a lower smoothed density D̅ᵢ of events, below 100.

It should be noted that, if D is the density of acoustic events per elementary cycle, its rolling average in the elementary cycle i, D̅ᵢ, is given by the following formula:

$${\overline{D}}_{i} = \frac{1}{N} {\sum }_{k = 0}^{N - 1} {D}_{i - k}$$

where N represents the number of elementary cycles on which the mean is calculated.

In the example shown in FIG. 7, a mathematical relation f can be used to link the SOH with the density D̅ᵢ SOH=f(D̅ᵢ), this relation being formulated, for example, using equations or parameters defining the aforementioned two linear relations. The data which demonstrate this relation f are stored in a memory for future use, so that they can be used to determine the state of health of a battery during its use.

When a battery of the type used in the test phase to obtain the aforementioned relation SOH=f(D̅ᵢ) is used, it is possible to execute a method using these data to calculate or determine the state of health SOH of the battery on the basis of current values of the parameter D found by detection of acoustic events, preferably by using a rolling average D̅ᵢ in the case where the relation found after testing was obtained by taking into account density values D̅ᵢ which were filtered, in other words averaged. Thus a user can reliably know the state of health of a battery on the basis of a detection of acoustic events.

An embodiment of a device 2 for monitoring a battery 1, comprising one or more electrochemical cells, is described below with reference to FIG. 8. The monitoring device is based on the detection and analysis of the acoustic emissions created in the battery. For this purpose, the monitoring device primarily comprises a device 3 for acquiring data relating to acoustic emissions created in the battery, and a processing device 4 for determining the state of health of the battery.

The data acquisition device may comprise one or more acoustic wave sensors 3a, 3b placed, for example, in contact with an electrochemical cell, or on the casing of the battery if it is not desired to “dedicate” a sensor to one electrochemical cell.

The acquisition device 3 is intended to detect the acoustic emissions created in the battery 1 and to convert them into a signal, notably an electrical signal. For this purpose, the acquisition device is preferably placed as close as possible to the place of creation of the acoustic emissions. In particular, it is useful to position the acquisition device on a wall of the cell or of the battery, for example on one face of the cell or battery. Thus the acoustic emissions can reach the acquisition device by passing through only the components of the cell or battery. The acquisition device may therefore be fastened to a cell or to the battery. A first sensor element may be positioned on a positive terminal. A second sensor element may be positioned on a negative terminal. The acquisition device may be of the acoustic type or of another type, such as an accelerometer, the important feature being that it can detect the acoustic emissions created in the cell or battery and convert them into a signal that can be analysed. The acquisition device may be of the piezoelectric type. Notably, the acquisition device can be used to detect and convert acoustic emissions whose frequency is in the range from 1 kHz to 3 MHz, in particular from 50 kHz to 1.5 MHz.

The acquisition device further comprises, in this example, a device 3c for eliminating outlier data, which may, for example, be based on any multiple detections in the case where a plurality of sensors are used.

The signal obtained at the output of the acquisition device is a function of the phenomenon generating the acoustic emissions and of the transmission of the acoustic emissions in the cell or in the battery to the acquisition device, and a function of the conversion by the acquisition device of the signal received by the sensor or sensors into an output signal.

The output signal of the acquisition device is then sent to the signal processing device 4. For example, this signal processing device comprises a preamplifier 5, a filter, an amplifier 7, and, if required, an electrical signal shaping element which is not shown.

This processing device 4 can be used to characterize the acoustic emissions detected in the battery by analysing each acoustic signal received by means of an analysis device 8. The analysis device can be used to determine one or more parameters of the acoustic signal, as defined below, and, on the basis of these values, to obtain a state of health value of the battery by using the method of the present invention. This state of health value SOH can then be used by any other system. Notably, the state of health value may be transmitted to a human-machine interface enabling a user to be informed of the state of health of the battery.

The monitoring device comprises all the hardware and/or software elements for implementing the monitoring method proposed by the invention.

Part of the acquisition device may comprise software means. Similarly, part of the processing device, or all of it, may comprise software means.

Different embodiments of a method for determining the state of health of a battery according to the invention are described below. In a characterization method that can be executed in the factory, a relation is established, for a particular type of battery, between the state of health of the battery and a parameter reflecting the density of acoustic events in the battery. This relation can then be used to determine the state of health of a battery in the course of its life, as it is used.

The calibration method, and the subsequent method for determining the state of health of a battery using the relation defined by the characterization method, both use similar concepts and operations. The two methods “break down” the charge/discharge cycles or times into an elementary cycle, as described above. For each elementary cycle, the acoustic signals emitted by the battery are detected, and, for each acoustic signal, one or more characteristic parameters of the acoustic signal are determined. A density value D is then determined for each elementary cycle, based on the values taken by the characteristic parameter or parameters recorded for each acoustic signal measured during the elementary cycle.

FIG. 9 shows an acoustic signal recorded for an acoustic event of the battery. The characteristic parameters of the acoustic signal may correspond to one or more of the following parameters:
amplitude of the acoustic signal;
energy of the acoustic signal;
rise time of the acoustic signal;
frequency of the oscillations of the acoustic signal;
duration of the acoustic signal;
number of “hits” in the acoustic signal, a hit corresponding to a passage beyond a threshold;
frequency of acoustic hits, that is to say the number of acoustic hits per unit of time in the acoustic signal;
presence of an acoustic event, by detection, for example, of at least one hit, and, if necessary a minimum amplitude and/or time interval of the acoustic signal (a binary concept: presence=1 during the appearance of an acoustic signal).

It should be noted that the frequency of the peaks, hits or oscillations in an acoustic signal corresponding to a single acoustic event is to be differentiated from a frequency of occurrence of acoustic emissions over time.

On the basis of a characteristic parameter or a combination of characteristic parameters recorded for each acoustic signal during an elementary cycle, a density value D is calculated, representing the density of acoustic events recorded during the elementary cycle. In the simplest example, the density D may be equal to the number of times that the “presence” parameter is active during the elementary cycle. The density D may be equal to the sum of the amplitudes of each of the detected events, or may be equal to the sum of the products of amplitude×duration calculated for each of the events, and so on.

$$D = {\sum }_{j = 0}^{nE} Pj ;$$

The density D would thus be defined as follows where Pⱼ corresponds to the value of a parameter or a combination of parameter values recorded for a j-th acoustic signal of the elementary cycle, and nE corresponds to the number of events of the elementary cycle considered.

The density D may be a sum as in the case above, but it would be possible to use another function which would take into account the parameter value or values of each of the acoustic signals of the elementary cycle. However, in the present invention, it is essential for the function for the calculation of D to be a monotonic function, increasing or decreasing, as a function of the number of events detected in an elementary cycle.

Additionally, a density value D which is filtered (low pass) or smoothed, denoted D̅ᵢ, is preferably used for the current elementary cycle denoted i. This smoothed density, denoted D̅ᵢ, may advantageously correspond to a rolling average over a number N of elementary cycles, such that

$${\overline{D}}_{i} = \frac{1}{N} {\sum }_{k = 0}^{N - 1} {D}_{i - k} .$$

An example of a characterization method is described below with reference to FIG. 10. This characterization method is executed using new test batteries, which are charged and then discharged in a loop until the test batteries are judged to be dead or at the end of their life according to a minimum predetermined SOH criterion, for example a state of health value SOH of 60%. During these charge/discharge cycles, the state of health is evaluated by means of an evaluation device other than that of the present invention. For example, the ampere-hours in charging and discharging may be integrated to obtain a value of present capacity of the test battery, and this may then be compared with the initial capacity to obtain a state of health value. Additionally, during these test battery cycles, the time or the cycles are broken down into an elementary cycle by monitoring a cycle indicator C, which is, for example, reset to 0 for each new cycle and is equal to a reference value at the end of each elementary cycle.

The method is described in greater detail below, using the flow diagram of FIG. 10.

In an initial step 100, the cycle indicator C is initialized.

In a step 110, an acoustic event is detected.

In a step 120, one or more characteristic parameters P1 to Pm of the acoustic signal are calculated/determined, where m is an integer, and any combination of parameters P is calculated on the basis of the characteristic parameters P1 to Pm.

In a step 130, a density value D is calculated, equal to a function F of the parameters P recorded for each of the events recorded for the elementary cycle in progress. If the density D is equal to a sum of a parameter, for example the amplitude, recorded for each event, the value D is incremented whenever a new signal occurs in the elementary cycle in progress.

In a step 140, a check is made as to whether or not the current elementary cycle has terminated. If the answer is negative, the detection of the events continues, if necessary by returning to steps 110, 120 and then 130. If the answer is affirmative, the cycle indicator C is reinitialized by returning to step 100.

In a step 150, to which the method proceeds if the answer is positive in the preceding step (cycle terminated) a state of health value SOH is evaluated by means of the aforementioned associated evaluation device.

In a step 160, which may be optional if required, a smoothed density value D̅ᵢ is calculated for the elementary cycle i which has terminated, on the basis of the values, which may be known (after a number of cycles), of density Di found in the preceding cycles.

In a step 170, the state of health information SOHi, the recorded density value Di, and the smoothed density value D̅ᵢ corresponding to the elementary cycle i are stored.

In a step 180, executed at the end of the life of the test battery, a functional relation is defined between the state of health SOH and the density values Di, or preferably the density values D̅ᵢ.

The characterization method then terminates.

When a battery of the same type as the test battery is used, the functional relation found by the above characterization method can then be used to determine a state of health value as the battery is being used. An example of a method that can be used for this determination is shown in FIG. 11.

During the use of the battery, in steps 200 to 240, the acoustic emissions are monitored and the calculations are performed according to the same method as that used, respectively, in steps 100 to 140 described above.

At the end of each elementary cycle, that is to say when the answer to step 240 is positive, a smoothed density value D̅ᵢ is calculated, in a step 250, for the elementary cycle i which has terminated, on the basis of the values, which may be known (after a number of cycles), of density Di found in the preceding cycles or on the basis of the smoothed density values D̅ᵢ₋ₖ found previously.

In a step 260, the values Di and/or D̅ᵢ previously calculated for the cycle i are stored.

In a step 270, a current state of health value SOHᵢ for the cycle i is determined, on the basis of the previously calculated values Di or D̅ᵢ and the predefined functional relation between the state of health SOH density values Di or the smoothed density values D̅ᵢ.

According to one embodiment of the characterization method and subsequently of the method for determining the SOH, only the information on the state of health SOHᵢ and the density Di or D̅ᵢ is stored for each cycle (see step 170) in a database, and this database is then used in step 270 of the determination method for finding the present state of health of the battery. For this purpose, it is possible to use optimization algorithms, using the database and the density value to calculate a state of health.

According to another embodiment of the characterization method, and subsequently of the method of determining SOH, a functional relation is determined, as in step 180, between the state of health and the density Di or D̅ᵢ. This relation is, for example, stored in a calculation unit of the processing device 8. For example, the mathematical functional relation comprises an affine relation linking the density values to state of health values, or comprises a plurality of affine relations valid over distinct intervals of density. An affine relation is particularly simple to store and to use subsequently: it can be stored in a memory by recording only two values, namely a slope and a y-intercept. Similarly, it is particularly simple and resource-light to use this mathematical relation to calculate the state of health, given the density Di or D̅ᵢ.

If the battery which is used executes incomplete charge/discharge cycles, which is often the case, provision may be made to adapt the method of determining the state of health to allow for the type of cycles executed. In fact, FIG. 4 shows that the number of events is not uniform over the whole range of state of charge SOC. In the illustrated example, when the charge is high, with an SOC of more than 80%, the number of acoustic events is relatively small. Conversely, when the charge is low, with an SOC of less than 40%, the number of acoustic events is relatively large. Since the functional relation between the state of health and the acoustic density D is obtained for a given type of cycling, for example complete cycling, the use of this functional relation may lead to erroneous determination of the state of health if the state of charge of the battery is, for example, always greater than 50%. To allow for the characteristics of real cycling, it is possible to analyse the SOC (or another parameter providing similar information, such as the voltage) in the elementary cycles that are executed and to carry out a determination of the state of health while allowing for the recorded values of SOC.

One feasible correction is to execute different kinds of cycling in characterization phases, providing, for example, “high” cycling between an SOC of 50% and 100%, and “low” cycling between an SOC of 0% and 50%. In this way, two databases and consequently two functional relations are obtained, and can be used subsequently according to the nature of the cycles executed by the battery.

Alternatively, or additionally, provision may be made to use the method for determining SOH in certain conditions of battery use only. For example, provision may be made not to estimate the SOH if the SOC in the current cycle has been mostly greater than 80%, or mostly less than 20%, or any other threshold or criterion considered acceptable according to the type of battery.

The mathematical relations used to find the state of health given the acoustic density Di or D̅ᵢ advantageously comprise one or more affine relations valid over distinct intervals of acoustic density.

Thus, in other words, according to the invention, the method for determining the state of health of a battery comprises a first phase of detecting and/or acquiring data in operation, followed by a second phase of determination and/or analysis and/or processing of data, notably during operation, and then a third phase of determination of the state of health based on the use of the results of the second phase.

Preferably, in the method according to the invention, in the first phase, data are detected and/or acquired during operation, and notably at least one acoustic event is detected by the sensor in the course of an elementary cycle of use of the battery, corresponding to a period of use of the battery with charging and/or discharging operations. Thus, preferably, at least one acoustic event is detected by the sensor during operation, in the course of an elementary cycle of use of the battery, corresponding to a period of use of the battery with charging and/or discharging operations.

Preferably, in the method according to the invention, in the second phase, a parameter value is determined and/or data are analysed and/or processed, notably during operation. This second phase is executed during operation. Notably, in this second phase, the value of at least one parameter is determined for each acoustic signal detected in the course of the elementary cycle of use, and an acoustic density value is calculated, for the elementary cycle of use, according to a density calculation function taking into account said at least one parameter determined for each of the acoustic signals detected in the course of the cycle, the density calculation function being a monotonic function based on the number of events detected during the elementary cycle.

Preferably, in the method according to the invention, in the third phase, the state of health is determined on the basis of the results of the second phase. Notably, a state of health value corresponding to said previously calculated acoustic density value is calculated, on the basis of a functional relation or a predetermined database, making it possible to know the state of health for a given acoustic density value.

Throughout the present document, the term “in operation” is to be interpreted as “during functioning”, or “continuously”, or “while the battery is functioning, that is to say while the battery is performing its function by supplying a load or by being recharged by an electrical power source”. Advantageously, the term “in operation” excludes phases exclusively concerned with testing, in which a battery is disconnected from the load which it usually supplies and/or is disconnected from the electrical power source by which it is usually recharged. Thus this term excludes phases of pure and/or one-off diagnosis in which the battery is isolated to undergo tests.

In the case of phases of pure and/or one-off diagnosis, a battery no longer provides its services or no longer performs its functions. It is stressed according to a particular voltage and current profile (called a “check-up” profile), this profile being very different from a typical operating profile of a battery.

Thus, by means of the method according to the invention, the battery may, at each instant or continuously, perform the functions for which it is designed, notably the essential functions of supplying a load and recharging from an electrical power source. Continuity of the service or functions of the battery is thus provided. The determination of the state of health of the battery is carried out during the operation or use of the battery.

1. Method for determining a state of health of a battery, using a sensor of an acoustic activity of the battery, comprising:
detecting at least one acoustic event by the sensor in a course of an elementary cycle of use of the battery, corresponding to a period of use of the battery with at least one of (i) charging operation and (ii) discharging operation;
determining the value of at least one parameter for each acoustic signal detected in the course of the elementary cycle of use;
calculating, for the elementary cycle of use, a value of acoustic density according to a density calculation function taking into account said at least one parameter determined for each acoustic signal detected in the course of the elementary cycle, the density calculation function being a monotonic function based on a number of acoustic events detected during the elementary cycle;
calculating a state of health value corresponding to said previously calculated acoustic density value, on a basis of a functional relation or a predetermined database, making it possible to know the state of health for a given acoustic density value.

2. Method for characterizing a test battery, using a sensor of an acoustic activity of the test battery, comprising performing a plurality of successive test operations during successive elementary cycles of use of the test battery, each test operation comprising:
detecting at least one acoustic event by the sensor in a course of an elementary cycle of use of the test battery, corresponding to a period of use of the test battery with at least one of (i) charging operation and (ii) discharging operation;
determining a value of at least one parameter for each acoustic signal detected in the course of the elementary cycle of use;
determining, for the elementary cycle of use, a value of acoustic density according to a density calculation function taking into account said at least one parameter determined for each acoustic signal detected in the course of the elementary cycle, the density calculation function being a monotonic function based on a number of acoustic events detected during the elementary cycle;
determining, in the course of the elementary cycle or at an end thereof, a state of health of the test battery;
storing in a database the state of health and the acoustic density value determined previously for the elementary cycle concerned.

3. Method for characterizing a test battery according to claim 2, further comprising determining a functional relation which makes it possible to know the state of health of the test battery for a given acoustic density value, based on said database.

4. Method for determining the state of health of a battery according to claim 1, wherein the state of health value corresponding to the acoustic density value is calculated on the basis of a predefined database.

5. Method for determining the state of health of a battery according to claim 1, the state of health value corresponding to an acoustic density value is calculated on the basis of a predefined functional relation.

6. Method according to claim 1, wherein said at least one parameter corresponds to the detection of the at least one acoustic event and the acoustic density value defined for the elementary cycle corresponds to the number of events detected during the elementary cycle.

7. Method according to claim 1, comprising, following the determining of the acoustic density value for the current elementary cycle, calculating a smoothed acoustic density value corresponding to a mean of a plurality of most recent acoustic density values, wherein the smoothed acoustic density value is at least one of (i) stored in the database and (ii) used for the state of health calculation.

8. Method according to claim 1, wherein said at least one parameter of the acoustic signal is chosen from the following list:
amplitude of the acoustic signal;
energy of the acoustic signal;
rise time of the acoustic signal;
frequency of oscillations of the acoustic signal;
duration of the acoustic signal;
number of hits in the acoustic signal, a hit corresponding to a passage beyond a threshold;
frequency of acoustic hits, the frequency being a number of acoustic hits per unit of time in the acoustic signal;
presence of an acoustic event.

9. Method according to claim 8, wherein the acoustic density value corresponds to a sum of the values of said at least one parameter of the acoustic signal.

10. Method for determining the state of health of a battery according to claim 4, wherein the predefined database is determined by performing a plurality of successive test operations during successive elementary cycles of use of the test battery, each test operation comprising:
detecting at least one acoustic event by the sensor in a course of an elementary cycle of use of the test battery, corresponding to a period of use of the test battery with at least one of (i) charging operation and (ii) discharging operation;
determining a value of at least one parameter for each acoustic signal detected in the course of the elementary cycle of use;
determining, for the elementary cycle of use, a value of acoustic density according to a density calculation function taking into account said at least one parameter determined for each acoustic signal detected in the course of the elementary cycle, the density calculation function being a monotonic function based on a number of events detected during the elementary cycle;
determining, in the course of the elementary cycle or at an end thereof, a state of health of the test battery;
storing in a database the state of health and the acoustic density value determined previously for the elementary cycle concerned.

11. Method for determining the state of health of a battery according to claim 5, wherein the predefined functional relation is determined by performing a plurality of successive test operations during successive elementary cycles of use of the test battery, each test operation comprising:
detecting at least one acoustic event by the sensor in a course of an elementary cycle of use of the test battery, corresponding to a period of use of the test battery with at least one of (i) charging operation and (ii) discharging operation;
determining a value of at least one parameter for each acoustic signal detected in the course of the elementary cycle of use;
determining, for the elementary cycle of use, a value of acoustic density according to a density calculation function taking into account said at least one parameter determined for each acoustic signal detected in the course of the elementary cycle, the density calculation function being a monotonic function based on a number of events detected during the elementary cycle;
determining, in the course of the elementary cycle or at an end thereof, a state of health of the test battery;
storing in a database the state of health and the acoustic density value determined previously for the elementary cycle concerned; and
determining the functional relation which makes it possible to know the state of health of the test battery for a given acoustic density value, based on said database.

12. Method according to claim 2, wherein said at least one parameter corresponds to the detection of the at least one acoustic event and the acoustic density value defined for the elementary cycle corresponds to the number of events detected during the elementary cycle.

13. Method according to claim 2, comprising, following the determining of the acoustic density value for the current elementary cycle, calculating a smoothed acoustic density value corresponding to a mean of a plurality of most recent acoustic density values, wherein the smoothed acoustic density value is at least one of (i) stored in the database and (ii) used for the state of health calculation.

14. Method according to claim 2, wherein said at least one parameter of the acoustic signal is chosen from the following list:
amplitude of the acoustic signal;
energy of the acoustic signal;
rise time of the acoustic signal;
frequency of oscillations of the acoustic signal;
duration of the acoustic signal;
number of hits in the acoustic signal, a hit corresponding to a passage beyond a threshold;
frequency of acoustic hits, the frequency being a number of acoustic hits per unit of time in the acoustic signal;
presence of an acoustic event.

15. Method according to claim 14, wherein the acoustic density value corresponds to a sum of the values of said at least one parameter of the acoustic signal.

16. Method according to claim 3, wherein said at least one parameter corresponds to the detection of the at least one acoustic event and the acoustic density value defined for the elementary cycle corresponds to the number of events detected during the elementary cycle.

17. Method according to claim 3, comprising, following the determining of the acoustic density value for the current elementary cycle, calculating a smoothed acoustic density value corresponding to a mean of a plurality of most recent acoustic density values, wherein the smoothed acoustic density value is at least one of (i) stored in the database and (ii) used for the state of health calculation.

18. Method according to claim 3, wherein said at least one parameter of the acoustic signal is chosen from the following list:
amplitude of the acoustic signal;
energy of the acoustic signal;
rise time of the acoustic signal;
frequency of oscillations of the acoustic signal;
duration of the acoustic signal;
number of hits in the acoustic signal, a hit corresponding to a passage beyond a threshold;
frequency of acoustic hits, the frequency being a number of acoustic hits per unit of time in the acoustic signal;
presence of an acoustic event.

19. Method according to claim 18, wherein the acoustic density value corresponds to a sum of the values of said at least one parameter of the acoustic signal.

20. Method according to claim 4, wherein said at least one parameter corresponds to the detection of the at least one acoustic event and the acoustic density value defined for an elementary cycle corresponds to the number of events detected during the elementary cycle.
